(19) United States
(12) Patent Application Publication
(10) Pub. No.: US 2018/0130879 A1
(43) Pub. Date: May 10, 2018

(54) Integrated Cylindrical Power Cell Module and Manufacturing Method Thereof

(71) Applicant: Xinyi Xu, Taizhou City (CN)

(72) Inventor: Xinyi Xu, Taizhou City (CN)

(21) Appl. No.: 15/621,261

(22) Filed: Jun. 13, 2017

(30) Foreign Application Priority Data
Nov. 8, 2016 (CN) 201610981777.X

(51) Int. Cl. H01L 29/06; H01L 29/739; H02M 7/00; H02K 11/33; H01L 25/07

(52) U.S. Cl. CPC H01L 29/0696; H01L 29/7394; H01L 25/071; H02K 11/33; H02M 7/003

(57) ABSTRACT

The present invention relates to an integrated cylindrical power cell module and a manufacturing method thereof, and belongs to the field of power cells. The cylindrical cells in the present invention are placed in the mounting holes corresponding to each other one by one on a first housing and a second housing, and both poles of the cylindrical cell are respectively fitted on heat management modules by a heat-conducting adhesive. In this way, the cylindrical cell is light in weight, low in cost, and good in sealing performance and also in heat dissipation. Temperature acquisition modules are provided on a cylindrical surface and two poles of the cylindrical cell to coordinate with the heat management modules, allowing the cylindrical cell to have a better operating temperature. Conical guideposts surrounding the mounting holes are provided around the mounting holes.

### CROSS REFERENCE TO RELATED APPLICATION

This application claims priority to Chinese Patent Application No. 201610981777.X, filed on 8 Nov. 2016, the contents of which are hereby incorporated by reference in their entirety.

### TECHNICAL FIELD

The present invention belongs to the field of power cells, and in particular to an integrated cylindrical power cell module and a manufacturing method thereof.

### BACKGROUND OF THE PRESENT INVENTION

At present, the production of power cell modules mainly depends upon a semi-automatic mode assisted by manual intervention. This mode has a low production efficiency, and the quality and consistency of products cannot be promised. Power cells in the prior art are fixed by a process in which all the cell is encapsulated and sealed by a heat-conducting adhesive. This increases the weight of the power cell units. In addition, when a failure occurs in certain cells in the power cell units, it is difficult to dismount the faulted cells, and other cells, which are in good condition, are likely to be damaged. Meanwhile, when power cells are removed from new energy vehicles since the power cells reach the end of their service life in accordance with the national standard, considerable capacity and a wide application range remain in the cells. Thus, the cells can be reused, and there is a wide market for power cells to be reused. However, the process in which all the cells are fixed by encapsulating and sealing the cells with a heat-conducting adhesive brings trouble to the reuse of power cells. For example, when the performance of certain cells is too low to be reused, or even when certain cells are damaged, it seems very hard to dismount these cells.

In addition, the existing schemes for cooling modules mainly include air cooling and liquid cooling. Air cooling has disadvantages such as a sharp temperature difference between the air inlet and the air outlet, uneven heat dissipation, and low heat dissipation efficiency and sealing performance. Liquid cooling has disadvantages such as complicated system, high cost and heavy weight, and the safe reliability is hard to be guaranteed. When a cell module is to be heated, a heating system is to be redesigned inside a cell pack.

As a result of doing so, on one hand, the power cell system becomes too complicated, a space for the heating system is to be reserved when designing the power cells, and consequently, the limited space in a vehicle is occupied and the maintenance in the future becomes inconvenient; and on the other hand, the quality and safety can be guaranteed only if the mounting process is done in the original factory, and quality warranty and compensation are not supported if the mounting process is not done in the original factory.

### SUMMARY OF THE PRESENT INVENTION

With regard to this, the purpose of the present invention is to overcome defects in the prior art and provide an integrated cylindrical power cell module with simple structure, light weight and convenient maintenance, and a manufacturing method thereof.

In order to achieve the aforementioned purpose, the present invention employs the following technical solutions.

An integrated cylindrical power cell module is provided, including a plurality of cylindrical cells, a plurality of jumpers, a housing for placing the cylindrical cells, heat management modules, temperature acquisition modules and a processor module;

wherein, the housing consists of a first housing and a second housing, the first housing and the second housing have jointing surfaces matched with each other; a plurality of mounting holes corresponding to each other one by one are formed in the first housing and the second housing; a plurality of jumpers are respectively provided on the first housing and the second housing, the jumpers on the first housing and the second housing are arranged oppositely, and the jumpers on the first housing have a same shape as the opposite jumpers on the second housing; holes are formed on the jumpers at positions corresponding to the mounting holes; two ends of the cylindrical cell are respectively placed in the mounting holes in the first housing and the second housing; and the first housing and the second housing are jointly fixed;

two poles of the cylindrical cell are respectively connected to the corresponding jumpers; a positive terminal and a negative terminal are provided on the housing; and the jumpers connected to the positive pole of the cylindrical cell are connected to the positive terminal, and the jumpers connected to the negative pole of the cylindrical cell are connected to the negative terminal;

the heat management modules are respectively provided on the first housing and the second housing, and two poles of the cylindrical cell are respectively fitted on the heat management modules by a heat-conducting adhesive; and

the temperature acquisition modules are respectively provided on a cylindrical surface, the positive terminal and the negative terminal of the cylindrical cell, and the temperature acquisition modules and the jumpers are respectively connected to the processor module.

Further, the temperature acquisition module includes a temperature acquisition element and a metal heat-conducting fin, and the temperature acquisition element is fixed on the metal heat-conducting fin by the heat-conducting adhesive.

Further, the metal heat-conducting fin is fixed on the cylindrical surface of the cylindrical cell by the heat-conducting adhesive.

Further, the metal heat-conducting fin is fixed on the positive terminal and the negative terminal.

Further, the heat management module includes a heat-conducting substrate and a thermoelectric element, a heat channel is provided in the heat-conducting substrate, and the thermoelectric element is placed in the heat channel.

Further, a boss and/or groove is provided on a jointing surface of the first housing, and a groove and/or boss, which is matched with the boss and/or groove on the jointing surface of the first housing, is respectively provided on the jointing surface of the second housing at a position corresponding to the boss and/or groove on the jointing surface of the first housing.

Further, conical guideposts surrounding the mounting holes are provided around the mounting holes on the first housing and the second housing.

A method for manufacturing the integrated cylindrical power cell module, including the following steps:

S1: respectively hot-riveting and fixing the jumpers on the first housing and the second housing:

S2: placing the cylindrical cells in the mounting holes on the second housing, and jointly fixing the first housing and the second housing;

S3: welding two poles of the cylindrical cell onto the corresponding jumpers by leads, respectively, connecting the jumpers connected to the positive pole of the cylindrical cell to the positive terminal, and connecting the jumpers connected to the negative pole of the cylindrical cell to the negative terminal;

S4: providing a positioning post on the housing for mounting the processor module, forming a positioning hole corresponding to the positioning post on the processor module, mounting the processor module on the housing, and connecting the jumpers to the processor module;

S5: respectively injecting a heat-conducting adhesive into both poles of the cylindrical cell, fitting the heat management modules on the heat-conducting adhesive, and fixing the heat management modules on the housing by screws, and connecting the heat management modules to the temperature voltage acquisition modules; and

S6: respectively arranging the temperature acquisition modules on a cylindrical surface, the positive terminal and the negative terminal of the cylindrical cell, and connecting the temperature acquisition modules to the processor module.

Further, in the step S2, conical guideposts surrounding the mounting holes are provided around the mounting holes, the cylindrical cells are placed in the mounting holes on the second housing along the conical guideposts on the second housing; and when the first housing is jointed to the second housing, the cylindrical cells are placed in the mounting holes on the first housing along the conical guideposts on the first housing, and the first housing and the second housing are fixed by screws.

Further, in the step S2, a boss and/or groove is provided on a jointing surface of the first housing, and a groove and/or boss, which is matched with the boss and/or groove on the jointing surface of the first housing, is respectively provided on the jointing surface of the second housing at a position corresponding to the boss and/or groove on the jointing surface of the first housing; and the first housing and the second housing are jointly fixed by the boss and groove, which are matched with each other.

With the above technical solutions, the present invention has at least the following beneficial effects.

The present invention provides an integrated cylindrical power cell module and a manufacturing method thereof. The cylindrical cells are placed in mounting holes corresponding to each other one by one in the first housing and the second housing, and two poles of the cylindrical cell are respectively fitted on the heat management modules by a heat-conducting adhesive. In the present invention, the heat management modules are fixed by applying the heat-conducting adhesive to two poles of the cylindrical cell. Compared with the mode in which all the cells are encapsulated and sealed by the heat-conducting adhesive, the present invention has the advantages of lighter weight and lower cost. Compared with liquid cooling, the present invention has the advantage of lower cost, and compared with air cooling, the present invention has the advantages of better sealing performance and heat dissipation. In addition, poles of the cylindrical cell can be sealed and protected. Temperature acquisition modules are respectively provided on a cylindrical surface of the cylindrical cell and two terminals of the integrated cylindrical power cell module to acquire, together with the heat management modules, the temperature of module terminals and of the cell itself. In this way, the heat management modules can be controlled more precisely so that the cylindrical cells can have a better operating temperature, and the number of times to charge and discharge of the cell and the endurance thereof can be increased. Conical guideposts surrounding the mounting holes are provided around the mounting holes on the first housing and the second housing. On one hand, with the conical guideposts, it is more convenient to place cells in the housing, the cells are not required to be completely fitted with the mounting holes, and instead, the cells can be guided into the mounting holes along the conical guideposts. In this way, there will be a lower error rate and a higher mounting efficiency. On the other hand, the arrangement of the conical guideposts overcomes the defect that an insulating film on an outer surface of the cylindrical cell is worn and cracked at the entrance of the mounting hole and thus the insulating performance of the cell is degraded.

### BRIEF DESCRIPTION OF THE DRAWINGS

FIG. 1 is a schematic view of the jointing of the first housing and the second housing, according to the present invention;

FIG. 2 is a schematic view of the mounting of the heat management modules, according to the present invention;

FIG. 3 is a schematic view of the first housing according to the present invention;

FIG. 4 is a schematic view of the second housing according to the present invention;

FIG. 5 is a schematic view of the arrangement of the temperature acquisition modules on the cylindrical surface of the cylindrical cell, according to the present invention;

FIG. 6 is a schematic view of the arrangement of the temperature acquisition modules on the terminals, according to the present invention; and

FIG. 7 is a schematic view of the thermoelectric module according to the present invention,

in which:
1: cylindrical cell;
2: jumper;
3A: first housing;
3B: second housing;
301: mounting hole;
302: positive terminal;
303: negative terminal;
304: boss;
305: groove;
306: conical guidepost;
4: heat management module;
401: heat-conducting substrate;
402: thermoelectric element;
501: temperature acquisition element;
502: metal heat-conducting fin; and
6: processor module.

### DETAILED DESCRIPTION OF THE PRESENT INVENTION

The technical solutions of the present invention will be further described in detail with reference to the accompanying drawings and embodiments.

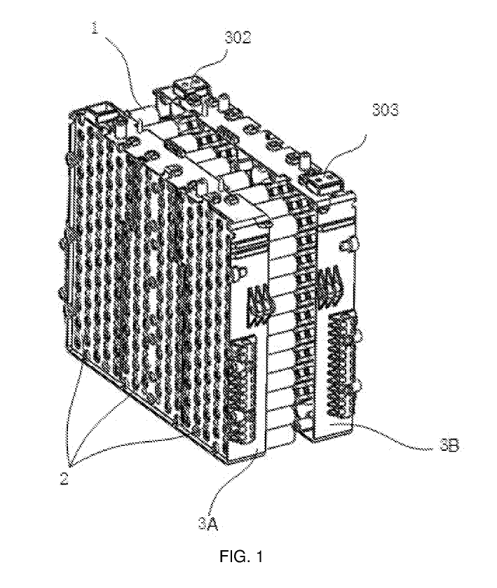

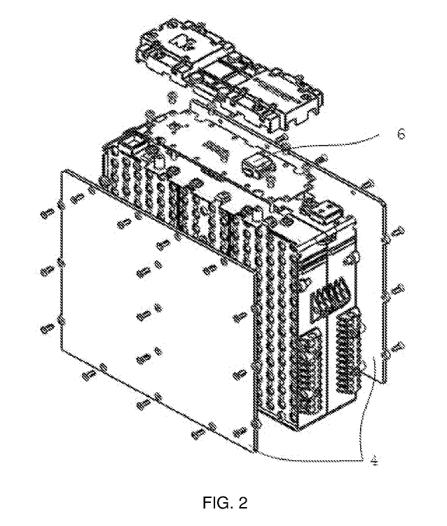

As shown in FIGS. 1 to 3, the present invention provides an integrated cylindrical power cell module, including a plurality of cylindrical cells 1, a plurality of jumpers 2, a housing for placing the cylindrical cells, heat management modules 4, temperature acquisition modules and a processor module 6;

wherein,

the housing consists of a first housing 3A and a second housing 3B, the first housing 3A and the second housing 3B have jointing surfaces matched with each other; a plurality of mounting holes 301 corresponding to each other one by one are formed in the first housing 3A and the second housing 3B; a plurality of jumpers 2 are respectively provided on the first housing 3A and the second housing 3B, the jumpers 2 on the first housing 3A and the second housing 3B are arranged oppositely, and the jumpers 2 on the first housing 3A have a same shape as the opposite jumpers 2 on the second housing 3B; holes are formed on the jumpers 2 at positions corresponding to the mounting to holes 301; two ends of the cylindrical cell 1 are respectively placed in the mounting holes 301 in the first housing 3A and the second housing 3B; and the first housing 3A and the second housing 3B are jointly fixed;

two poles of the cylindrical cell 1 are respectively connected to the corresponding jumpers 2; a positive terminal 302 and a negative terminal 303 are provided on the housing; and the jumpers 2 connected to the positive pole of the cylindrical cell 1 are connected to the positive terminal 302, and the jumpers 2 connected to the negative pole of the cylindrical cell 1 are connected to the negative terminal 303;

the heat management modules 4 are respectively provided on the first housing 3A and the second housing 3B, and two poles of the cylindrical cell 1 are respectively fitted on the heat management modules 4 by a heat-conducting adhesive; and

the temperature acquisition modules are respectively provided on a cylindrical surface, the positive terminal 302 and the negative terminal 303 of the cylindrical cell 1, and the temperature acquisition modules and the jumpers 2 are respectively connected to the processor module 6.

It can be understood that the cylindrical cells 1 are placed in mounting holes 301 corresponding to each other one by one in the first housing 3A and the second housing 3B, and two poles of the cylindrical cell 1 are respectively fitted on the heat management modules 4 by a heat-conducting adhesive. In the present invention, the heat management modules 4 are fixed by applying to the heat-conducting adhesive to two poles of the cylindrical cell 1. Compared with the mode in which all the cells are encapsulated and sealed by the heat-conducting adhesive, the present invention has the advantages of lighter weight and lower cost. Compared with liquid cooling, the present invention has the advantage of lower cost, and compared with air cooling, the present invention has the advantages of better sealing performance and heat dissipation. In addition, poles of the cylindrical cell 1 can be sealed and protected. Temperature acquisition modules are respectively provided on a cylindrical surface of the cylindrical cell 1 and the two terminals (302, 303) of the integrated cylindrical power cell module to acquire, together with the heat management modules 6, the temperature of module terminals and of the cell itself. In this way, the heat management modules 4 can be controlled more precisely so that the cylindrical cell 1 can have a better operating temperature, and the number of times to charge and discharge of the cell and the endurance thereof can be increased.

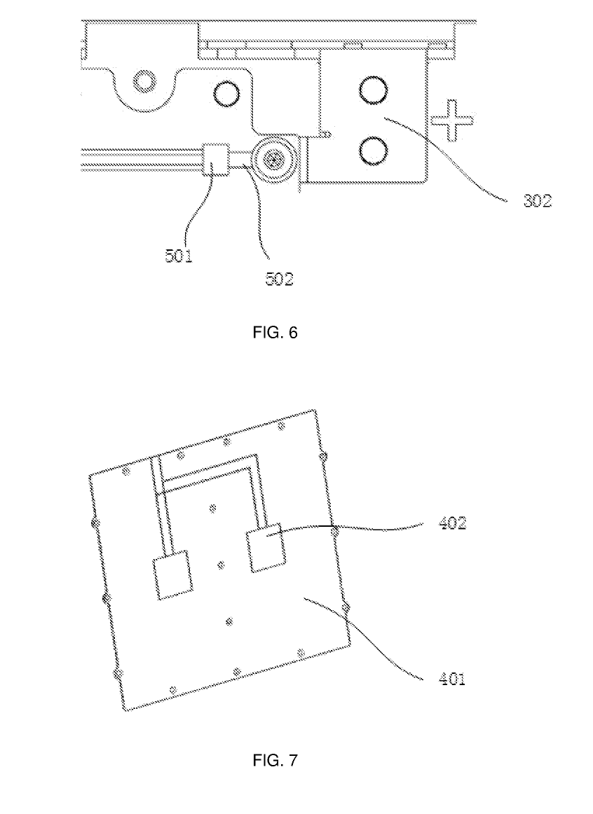

The temperature acquisition module of the present invention is preferably designed as follows. As shown in FIG. 5 and FIG. 6, the temperature acquisition module of the present invention is preferably designed to include a temperature acquisition element 501 and a metal heat-conducting fin 502, the temperature acquisition element 501 being fixed on the metal heat-conducting fin 502 by the heat-conducting adhesive. Further, as shown in FIG. 5, the metal heat-conducting fin 502 is fixed on the cylindrical surface of the cylindrical cell 1 by the heat-conducting adhesive. As shown in FIG. 6, the metal heat-conducting fin 502 is fixed on the positive terminal 202 and the negative terminal 303.

The heat management module 4 of the present invention is preferably designed as follows. As shown in FIG. 7, the heat management module 4 includes a heat-conducting substrate 401 and a thermoelectric element 402, a heat channel is provided in the heat-conducting substrate 401, and the thermoelectric element 402 is placed in the heat channel. Compared with the situation in which a heating system is traditionally separated from a cooling system, in the present invention, the thermoelectric element 402 is preferred, and by the thermoelectric principle, the heat management system integrating the heating system and the cooling system is realized. In this way, the present invention has the advantages of lower cost, simpler structure, lighter weight and more convenient dismounting and maintaining process.

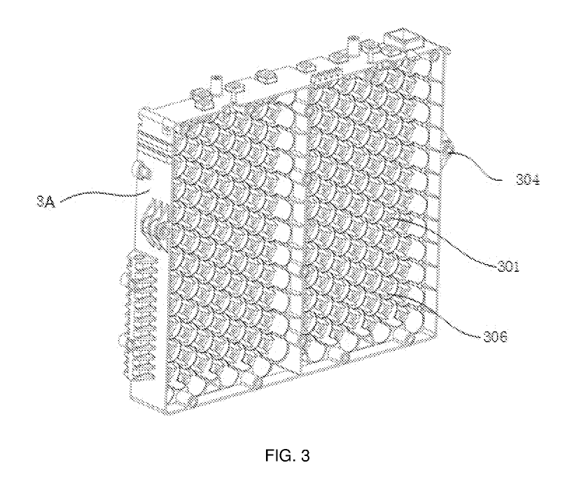

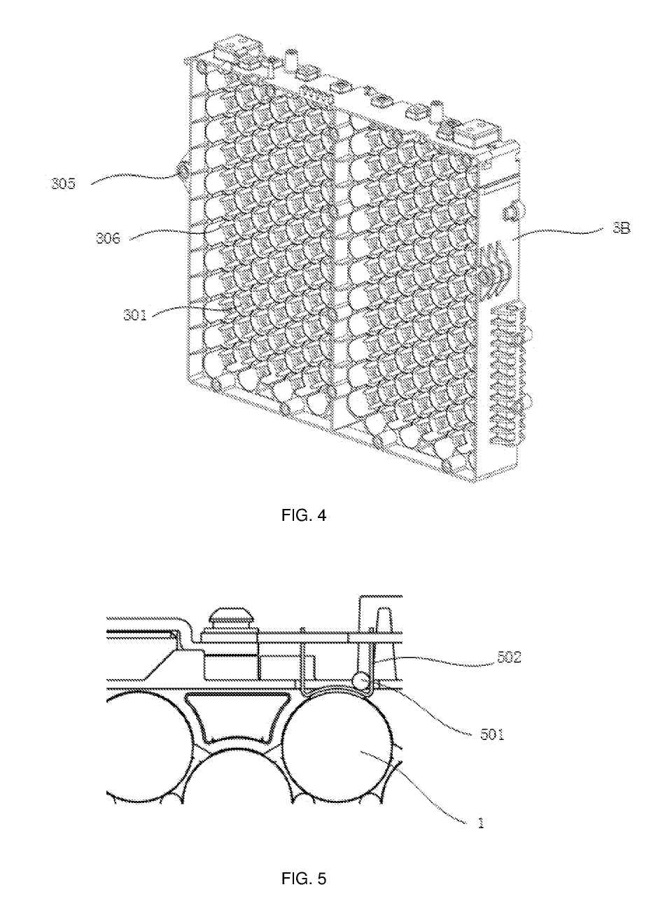

Further, as shown in FIG. 3 and FIG. 4, a boss 304 and/or groove 305 is provided on a jointing surface of the first housing 3A, and a groove 305 and/or boss 304, which is matched with the boss 304 and/or groove 305 on the jointing surface of the first housing 3A, is respectively provided on the jointing surface of the second housing 3B at a position corresponding to the boss 304 and/or groove 305 on the jointing surface of the first housing 3A. It can be understood that a boss 304 and a groove 305 with male and female features are provided on the first housing 3A and the second housing 3B, which are coordinated to test the consistency in size of the first housing 3A and the second housing 3B. When the inconsistency in size goes beyond a certain tolerance range, the two housings cannot be matched. In this way, the precision in assembly can be guaranteed, and the imprecision in assembly caused by an excessive size difference in housings can be effectively prevented.

Further, as shown in FIG. 3 and FIG. 4, conical guideposts 306 surrounding the mounting holes 301 are provided around the mounting holes 301 on the first housing 3A and the second housing 3B.

It can be understood that conical guideposts 306 surrounding the mounting holes 301 are provided around the mounting holes 301 on the first housing 3A and the second housing 3B. On one hand, with the conical guideposts 306, it is more convenient to place the cylindrical cells 1 in the housing, the cylindrical cells 1 are not required to be completely fitted with the mounting holes 301, and instead, the cells can be guided into the mounting holes 301 along the conical guideposts 306. In this way, there will be a lower error rate and a higher mounting efficiency. On the other hand, the arrangement of the conical guideposts overcomes the defect that an insulating film on an outer surface of the cylindrical cell 1 is worn and cracked at the entrance of the mounting hole 301 and thus the insulating performance of the cylindrical cell 1 is degraded.

The present invention also provides a method for manufacturing an integrated cylindrical power cell module,

including the following steps:

S1: respectively hot-riveting and fixing the jumpers 2 on the first housing 3A and the second housing 3B:

S2: placing the cylindrical cells 1 in the mounting holes 301 on the second housing 3B, and jointly fixing the first housing 3A and the second housing 3B;

S3: welding two poles of the cylindrical cell 1 onto the corresponding jumpers 2 by leads, respectively, connecting the jumpers 2 connected to the positive pole of the cylindrical cell 1 to the positive terminal 302, and connecting the jumpers 2 connected to the negative pole of the cylindrical cell 1 to the negative terminal 303;

S4: providing a positioning post on the housing for mounting the processor module 6, forming a positioning hole corresponding to the positioning post on the processor module 6, mounting the processor module 6 on the housing, and connecting the jumpers 2 to the processor module 6;

S5: respectively injecting a heat-conducting adhesive into both poles of the cylindrical cell 1, fitting the heat management modules 4 on the heat-conducting adhesive, and fixing the heat management modules 4 on the housing by screws, and connecting the heat management modules 4 to the temperature voltage acquisition modules; and

S6: respectively arranging the temperature acquisition modules on a cylindrical surface, the positive terminal 302 and the negative terminal 303 of the cylindrical cell 1, and connecting the temperature acquisition modules to the processor module 6.

Further, in the step S2, conical guideposts 306 surrounding the mounting holes 301 are provided around the mounting holes 301, the cylindrical cells 1 are placed in the mounting holes 301 on the second housing 3B along the conical guideposts 306 on the second housing 3B; and when the first housing 3A is jointed to the second housing 3B, the cylindrical cells 1 are placed in the mounting holes 301 on the first housing 3A along the conical guideposts 306 on the first housing 3A, and the first housing 3A and the second housing 3B are fixed by screws.

Further, in the step S2, a boss 304 and/or groove 305 is provided on a jointing surface of the first housing 3A, and a groove 305 and/or boss 304, which is matched with the boss 304 and/or groove 305 on the jointing surface of the first housing 3A, is respectively provided on the jointing surface of the second housing 3B at a position corresponding to the boss 304 and/or groove 305 on the jointing surface of the first housing 3A; and the first housing 3A and the second housing 3B are jointly fixed by the boss 304 and groove 305, which are matched with each other.

The purposes, technical solutions and beneficial effects of the present invention have been described in detail by the above specific embodiments. It should be understood that the foregoing descriptions are mere specific embodiments of the present invention and are not intended to limit the protection scope of the present invention. Any modifications, equivalent replacements, improvements made within the spirit and principle of the present invention shall fall into the protection scope of present invention.

What is claimed is:

1. An integrated cylindrical power cell module, comprising a plurality of cylindrical cells, a plurality of jumpers, a housing for placing the cylindrical cells, heat management modules, temperature acquisition modules and a processor module;
wherein,
the housing consists of a first housing and a second housing, the first housing and the second housing have jointing surfaces matched with each other; a plurality of mounting holes corresponding to each other one by one are formed in the first housing and the second housing; a plurality of jumpers are respectively provided on the first housing and the second housing, the jumpers on the first housing and the second housing are arranged oppositely, and the jumpers on the first housing have a same shape as the opposite jumpers on the second housing; holes are formed on the jumpers at positions corresponding to the mounting holes; two ends of the cylindrical cell are respectively placed in the mounting holes in the first housing and the second housing; and the first housing and the second housing are jointly fixed;
two poles of the cylindrical cell are respectively connected to the corresponding jumpers; a positive terminal and a negative terminal are provided on the housing; and the jumpers connected to the positive pole of the cylindrical cell are connected to the positive terminal, and the jumpers connected to the negative pole of the cylindrical cell are connected to the negative terminal;
the heat management modules are respectively provided on the first housing and the second housing, and two poles of the cylindrical cell are respectively fitted on the heat management modules by a heat-conducting to adhesive; and
the temperature acquisition modules are respectively provided on a cylindrical surface, the positive terminal and the negative terminal of the cylindrical cell, and the temperature acquisition modules and the jumpers are respectively connected to the processor module.

2. The integrated cylindrical power cell module according to claim 1, characterized in that the temperature acquisition module comprises a temperature acquisition element and a metal heat-conducting fin, and the temperature acquisition element is fixed on the metal heat-conducting fin by the heat-conducting adhesive.

3. The integrated cylindrical power cell module according to claim 2, characterized in that the metal heat-conducting fin is fixed on the cylindrical surface of the cylindrical cell by the heat-conducting adhesive.

4. The integrated cylindrical power cell module according to claim 2, characterized in that the metal heat-conducting fin is fixed on the positive terminal and the negative terminal.

5. The integrated cylindrical power cell module according to claim 1, characterized in that the heat management module comprises a heat-conducting substrate and a thermoelectric element, a heat channel is provided in the heat-conducting substrate, and the thermoelectric element is placed in the heat channel.

6. The integrated cylindrical power cell module according to claim 1, characterized in that a boss and/or groove is provided on a jointing surface of the first housing, and a groove and/or boss, which is matched with the boss and/or groove on the jointing surface of the first housing, is respectively provided on the jointing surface of the second housing at a position corresponding to the boss and/or groove on the jointing surface of the first housing.

7. The integrated cylindrical power cell module according to claim 1, characterized in that conical guideposts surrounding the mounting holes are provided around the mounting holes on the first housing and the second housing.

8. A method for manufacturing the integrated cylindrical power cell module according to claim 1,
comprising the following steps:
S1: respectively hot-riveting and fixing the jumpers on the first housing and the second housing:
to S2: placing the cylindrical cells in the mounting holes on the second housing, and jointly fixing the first housing and the second housing;
S3: welding two poles of the cylindrical cell onto the corresponding jumpers by leads, respectively, connecting the jumpers connected to the positive pole of the cylindrical cell to the positive terminal, and connecting the jumpers connected to the negative pole of the cylindrical cell to the negative terminal;
S4: providing a positioning post on the housing for mounting the processor module, forming a positioning hole corresponding to the positioning post on the processor module, mounting the processor module on the housing, and connecting the jumpers to the processor module;
S5: respectively injecting a heat-conducting adhesive into both poles of the cylindrical cell, fitting the heat management modules on the heat-conducting adhesive, and fixing the heat management modules on the housing by screws, and connecting the heat management modules to the temperature voltage acquisition modules; and
S6: respectively arranging the temperature acquisition modules on a cylindrical surface, the positive terminal and the negative terminal of the cylindrical cell, and connecting the temperature acquisition modules to the processor module.

9. The method according to claim 8, characterized in that:
to in the step S2, conical guideposts surrounding the mounting holes are provided around the mounting holes, the cylindrical cells are placed in the mounting holes on the second housing along the conical guideposts on the second housing; and when the first housing is jointed to the second housing, the cylindrical cells are placed in the mounting holes on the first housing along the conical guideposts on the first housing, and the first housing and the second housing are fixed by screws.

10. The method according to claim 8, characterized in that:
in the step S2, a boss and/or groove is provided on a jointing surface of the first housing, and a groove and/or boss, which is matched with the boss and/or groove on the jointing surface of the first housing, is respectively provided on the jointing surface of the second housing at a position corresponding to the boss and/or groove on the jointing surface of the first housing; and the first housing and the second housing are jointly fixed by the boss and groove, which are matched with each other.
